(19) United States
(12) Patent Application Publication
(10) Pub. No.: US 2022/0212947 A1
(43) Pub. Date: Jul. 7, 2022

(54) Methods of Tailoring The Optical Properties of Transition Metal Dichalcogenides

(71) Applicant: Government of the United States, as represented by the Secretary of the Air Force, Wright-Patterson AFB, OH (US)

(72) Inventors: Jonathan P. Vernon, Beavercreek, OH (US); Peter R. Stevenson, Dayton, OH (US); William J. Kennedy, Dayton, OH (US)

(21) Appl. No.: 17/644,574

(22) Filed: Dec. 16, 2021

Related U.S. Application Data
(60) Provisional application No. 63/133,974, filed on Jan. 5, 2021.

(51) Int. Cl. C01G 39/06; C23C 14/02; C23C 16/02

(52) U.S. Cl. CPC C01G 39/06; C01P 2006/60; C23C 16/02; C23C 14/02

(57) ABSTRACT

A method for controlling the optical properties of a material comprises the steps of (1) applying a dopant to an undoped TMD film by solution dip-coating the TMD, wherein the solution is a dopant solution consisting of one of NADH (nicotinamide adenine dinucleotide) and TCNQ (7,7,8,8-tetracyanoquinodimethane), wherein the doped TMD film exhibits an altered refractive index (n) and extinction coefficient (k) in comparison to the undoped TMD film. The dopant solution is a 0.1M solution of NADH in anhydrous acetonitrile or a 0.1M solution of TCNQ in anhydrous methanol. Rinsing the doped TMD film with a solvent consisting of one of anhydrous acetonitrile and anhydrous methanol to create an undoped TMD film exhibiting a refractive index (n) and extinction coefficient (k) substantially similar to the original undoped TMD film. The TMD is selected from the group consisting of MoS₂, MoSe₂, WS₂, WSe₂, and TiS₂.

Pursuant to 37 C.F.R. § 1.78(a)(4), this application claims the benefit of and priority to prior filed co-pending Provisional Application Ser. No. 63/133,974, filed 5 Jan. 2021, which is expressly incorporated herein by reference.

### RIGHTS OF THE GOVERNMENT

The invention described herein may be manufactured and used by or for the Government of the United States for all governmental purposes without the payment of any royalty.

### FIELD OF THE INVENTION

The present invention relates generally to methods for tailoring the optical properties of transition metal dichalcogenides and, more particularly, to methods for tailoring the optical properties of transition metal dichalcogenides through physisorbed dopant-induced interactions.

### BACKGROUND OF THE INVENTION

The optical constants of a material are fundamental in theoretical, experimental, and manufacturing strategies. As such, the ability to controllably tailor such optical properties is known to have profound consequences in material and optical device development. What is desired are methods for tailoring the semiconducting transition metal dichalcogenide optical constants in a reversible manner.

### SUMMARY OF THE INVENTION

Here, we illustrate that the optical constants (i.e., refractive index, n; and extinction coefficient, k) of transition metal dichalcogenides (TMDs) may be controllably changed by introducing organic or inorganic chemical dopants. For instance, the refractive index for molybdenum disulfide (MoS₂) may changed by ˜2 in the presence of physisorbed n-type and p-type chemical dopants.

The refractive index (n) for pristine monolayer MoS₂ in the near-infrared is predicted to be ≥4. The refractive index may decrease by ˜2 at energies below the band edge.

We have discovered that variability in the optical response may correspond to changes in oscillator amplitude and dielectric polarizability of all measured excitons, suggesting that charge transfer and local dielectric media effects are significant contributors. Monolayer metal organic chemical vapor deposited MoS₂ films are evaluated below using spectroscopic ellipsometry to assess changes in the refractive index (n) and extinction coefficient (k) due to dopant-induced screening effects from chemical adsorbates and mild film degradation. Notably, large reversible changes in the refractive index (Δn≈2.2) are observed by varying n- and p-type adsorbates. The extent of tailorable dopant-induced screening of MoS₂ optical constants illustrated herein is also shown to be highly dependent on film quality. The tailoring of semiconducting transition metal dichalcogenide optical constants in a reversible manner is expected to have broad implications in the development of optical and optoelectronic devices (e.g., low-dimensional excitonic optoelectronic devices, electroabsorption modulators, and high-efficiency optical components).

The present invention overcomes the foregoing problems and other shortcomings, drawbacks, and challenges of tailoring the optical properties of transition metal dichalcogenides in a reversible manner. While the invention will be described in connection with certain embodiments, it will be understood that the invention is not limited to these embodiments. To the contrary, this invention includes all alternatives, modifications, and equivalents as may be included within the spirit and scope of the present invention.

Herein we demonstrate the tailoring of semiconducting transition metal dichalcogenide (TMDs) refractive indices on the order of ˜2. The changes in response are unmatched by state of the art systems. Within the field of work involving TMDs, the ability to controllably change the refractive index in this fashion (and to this scale) is unreported.

There is an ever-increasing need for high refractive index and low extinction coefficient materials. The additional ability to control the optical properties of these materials remains a significant challenge. However, the control offered by the disclosed invention allows both high refractive index responses along with controlled tailoring, both of which provide significant advantages over state of the art semiconductor systems.

This invention has applications ranging from paint pigments to any field involving optical and optoelectronic devices. The advantages of this invention include the wide range of potential doping species that may be applied. In some cases, the doping species may also be removed or altered to thereby allow for the reversible tailoring of said optical properties.

According to one embodiment of the present invention a method for controlling the optical properties of MoS₂ comprises the steps of: applying a dopant to an undoped TMD film by solution dip-coating the TMD, wherein the solution is a dopant solution consisting of one of NADH (nicotinamide adenine dinucleotide) and TCNQ (7,7,8,8-tetracyanoquinodimethane), wherein the doped TMD film exhibits an altered refractive index (n) and extinction coefficient (k) in comparison to the undoped TMD film.

According to a first variation of the method, the dopant solution is a 0.05 to 0.5M, e.g. 0.1M, solution of NADH in anhydrous acetonitrile.

According to another variation of the method, the dopant solution is a 0.05 to 0.5M, e.g. 0.1M, solution of TCNQ in anhydrous methanol.

According to a further variation, the method further comprises rinsing the doped TMD film with a solvent consisting of one of anhydrous acetonitrile and anhydrous methanol to create an undoped TMD film exhibiting a refractive index (n) and extinction coefficient (k) substantially similar to the original undoped TMD film. ‘Substantially similar’ means within 10% of the values for the original undoped film.

The TMD for the method and any of the variations is selected from the group consisting of MoS₂, MoSe₂, WS₂, and WSe₂.

The TMD film is deposited onto the substrate by one of chemical vapor deposition (CVD), physical vapor deposition (PVD) with two-step annealing, and a liquid-phase exfoliation with polyoxometalates (POMs from artificial redox exfoliation) or through simple bath sonication using native redox exfoliation processes.

The disclosed method and materials may be combined in any manner to create the desired doped or undoped TMD films.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated into and constitute a part of this specification, illustrate embodiments of the present invention and, together with a general description of the invention given above, and the detailed description of the embodiments given below, serve to explain the principles of the present invention. The patent or application file contains at least one drawing executed in color. Copies of this patent or patent application publication with color drawing(s) will be provided by the Office upon request and payment of the necessary fee.

FIG. 1A is a representative AFM micrograph, with 1 μm scale bar, indicating continuous monolayer coverage of MOCVD MoS₂ films used throughout this work.

FIG. 1B illustrates the dip-coating and solvent rinse process for subsequent figures.

FIG. 1C compares dip-coated dopant-induced optical constants to an as-prepared MOCVD MoS₂ film. NADH is an n-type dopant and TCNQ is a p-type dopant.

FIG. 1D presents Δn responses showing the magnitude of dopant-induced screening tuning along with the change in response upon solvent washing to remove physisorbed dopants.

FIG. 1E presents Δk/k responses further illustrating changes in broadband exciton absorption with respect to optical constant modulation. Here, the first derivative for k of the as-prepared film is provided as a reference to Δk/k responses for NADH and TCNQ film conditions. Δk/k responses are normalized to the as-prepared k response at ˜0.413 eV (3000 nm). Exciton labels are in relation to the as-prepared peak locations.

FIGS. 2A-2B present normalized Δε responses for Δε₁ (FIG. 2A) and Δε₂ (FIG. 2B) with respect to the chemical adsorbates. Δε responses are normalized to the as-prepared response at ˜0.413 eV (3000 nm). Also note the NADH response is reported as −Δε to easily compare overall normalized magnitude and spectral characteristics. Exciton labels are in relation to the as-prepared peak locations.

FIG. 3 presents a comparison of MoS₂ n and k literature values related to A, B, and C peak exciton responses as well as out to 1000 nm where possible.

FIGS. 4A-4D present AFM phase contrast mapping with 1 μm scale bars. FIG. 4A presents an as-prepared MOCVD MoS₂ film; FIG. 4B presents a film annealed in air at 380° C. for 10 minutes; and FIG. 4C presents a film annealed in air at 380° C. for 20 minutes. In FIG. 4D, Mo mass oxidation (Mo+6 atomic mass percent, At %) is assessed using XPS showing (FIG. 4A) <3% oxidation for the as-prepared film, (FIG. 4B) ˜15% for the 10 minute film at 380° C., and (FIG. 4C) ˜23% for the 20 minute film at 380° C.

FIG. 4E presents Raman spectra showing decreased intensity in the E′ and A′ MoS₂ vibrational modes in relation to an increase in the sapphire substrate peak (*).

FIG. 4F presents Fitted Raman spectra (solid lines) showing minimal shift in frequency with ˜1 cm⁻¹ redshift for E′ and blueshift for A′.

FIG. 4G presents significant photoluminescence (PL) intensity quenching of the A exciton from the as-prepared film is shown with respect to the ambient air annealing films.

FIG. 5A presents the impact of ambient air annealing on the optical constants of MOCVD MoS₂.

FIG. 5B presents that the overall physisorbed dopant-induced n-type and p-type screening of MOCVD MoS₂ optical constants is likewise shown to decrease with the film annealed at 380° C. for 10 minutes.

FIG. 5C presents the film of FIG. 5B annealed at 380° C. for 20 minutes.

FIGS. 5D-5E present normalized Δε responses for Δε1 (FIG. 5D) and Δε2 (FIG. 5E) with respect to the chemical adsorbates and as-prepared or degraded film conditions. Δε responses are normalized to the as-prepared response at ˜0.413 eV (3000 nm).

Also note the NADH response is reported as −Δε to easily compare overall normalized magnitude and spectral characteristics. Exciton labels are in relation to the as-prepared peak locations.

FIG. 6A presents a horizontal hot-wall system for growing MOCVD monolayer MoS₂ films.

FIG. 6B presents a growth profile for monolayer MoS₂ MOCVD synthesis.

FIGS. 7A-7B present a comparison of different dispersion models in the analysis of as-prepared MOCVD MoS₂ optical constants n (FIG. 7A) and k (FIG. 7B). The axes ranges are adjusted to better illustrate changes in response due to the respective models.

FIG. 8A presents a representative real-space depiction of electrons and holes bound into excitons for 2D monolayer MoS₂ and 3D bulk layer MoS₂. In the case of layer-dependent MoS₂ quantum confinement, transition into bulk layer effects is observed to occur around ˜5 layers. Changes in the dielectric environment, due to representative exciton activity, are indicated schematically by ε2D and ε3D in relation to the permittivity of free space ε0.

FIG. 8B presents the qualitative impact of dimensionality on exciton absorption are schematically represented by optical absorption for monolayer excitons and bulk layer excitons. The transition from 2D to 3D is known to lead to a decrease of both the band gap and the exciton binding energy (black vertical arrow and horizontal teal double-sided arrow, respectively). This likewise corresponds to a decrease in exciton absorption with respect to a perfectly monolayer film (vertical orange double-sided arrow).

FIG. 9 presents resonant Raman spectra illustrating the longitudinal acoustic (LA) phonon in relation to E′ and A′. The minimal change in the LA phonon suggests there is very mild degradation of the films with ambient air annealing.

FIG. 10 presents representative photoluminescence spectrum (left) and 2D intensity map from a 1 mm² area (right) of an as-prepared MOCVD MoS₂ film illustrating uniformity of A exciton emission intensity. Photoluminescence mapping area is on the order of the spot size used in spectroscopic ellipsometry. The (*) in the spectrum denotes the substrate.

FIGS. 11-12 present refractive index (n) and extinction coefficient (k) data for MOCVD MoS₂ and MoSe₂.

FIGS. 13-16 present refractive index (n) and extinction coefficient (k) data for exfoliated WSe₂, WS₂, MoSe₂, and TiS₂, each of which was prepared by the same method described herein. The WSe₂, WS₂, MoSe₂, and TiS₂ datasets involve exfoliated few-to-monolayer nanoflake TMDs from bulk crystals. The bulk crystal TMDs were simply bath sonicated in ACN for up to 5 hours, centrifuged, and the various solutions prepared to make thin films for characterization. Neat TMD solutions were mixed with 0.1M dopant solutions (same organic dopants). The method used to exfoliate TMDs from bulk crystals follows:

(a) Add bulk TMD powder to glass container targeting 5 mg/mL of TMD, typically 15-50 mg for a 20 mL vial. This can scale to kimble flasks (250 mL) but takes longer the larger the container size. It was found that plastic containers will work but the process will take much longer.

(b) Add solvent to TMD powder to get approximately 5 mg/mL of TMD in solvent, but this does not need to be exact. It is desired to use solvents that are stable long term, e.g. acetonitrile (ACN), THF, NMP. Temporary stability may be achieved with water and short-chain alcohols.

(c) Seal the container tightly and cover with parafilm and place into a bath sonicator with the water level matching the solvent line inside the vial/container.

(d) Allow the sample to sonicate for several hours. A minimum 2 hours, longer will be better, generally aim for about 5 hours.

(e) Pull the sample out of the bath sonicator, allow to settle for 3-5 minutes.

(f) Carefully remove the supernatant and add to a centrifuge tube.

(g) Spin down at 5000 RCF (relative centrifugal force) for 15 minutes.

(h) With minimal movement as not to disturb the pellet formed at the bottom, remove the top ¾ of the colloid and place into a separate container.

(g) Return any pellet material to the original container to recycle for more exfoliated material.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

Semiconducting transition metal dichalcogenides (TMDs, MX₂ where M=Mo or W, and X=S, Se, or Te) continue to attract attention as components in optical devices due to notable refractive indices (e.g., n≥4 for MoS₂) in the ultraviolet to near-infrared wavelength regions. The optical constants (i.e., refractive index, n, and extinction coefficient, k) of a material are required for theoretical-experimental design strategies involving next-generation optical and optoelectronic devices. Relevant to optical performance, TMDs are known to be subject to strong excitonic effects. As an example, representative layer-dependent excitonic effects have been shown to change MoS₂ and WSe₂ optical constants due to quantum confinement (i.e., changes in electric-field screening with increasing TMD layers). The investigation of such characteristic radiative excitonic effects is nascent as novel TMD synthesis techniques continue to be developed. Likely related to progressive synthetic development, considerable variation in TMD optical constants are also reported in the literature without clear attribution to a prevailing material source or physical origin. Herein, we demonstrate how dopant-induced charge transfer and dielectric field screening effects are important considerations (within the framework of generalized excitonic effects) regarding MoS₂ optical constant variability and may also be used to reversibly tailor optical responses on the order of Δn≈2.2 under reported as-prepared film conditions.

In bulk semiconductors, n is dependent on the band gap of the material as it determines the threshold of incident photon absorption. As a result, any change in n is dependent on a subsequent change in the band gap, where very small modulation in n (e.g., Δ n=0.001 to 0.01 in most cases) for as-prepared bulk semiconductors is observed, even at doping levels >10²⁰ cm⁻³. For low-dimensional semiconductors, strong electron-electron and electron-phonon interactions can give rise to more complicated absorption and polarizability not solely dependent on the band gap of the material; as a result, the potential for greater change in n is possible.

Given the known complexity of low-dimensional exciton behavior, the qualitative term excitonic effects is broadly used to describe associated many-body phenomena. For example, excitonic effects may involve intricate enhanced electron-electron interactions, exciton dispersion and transport, electric-field screening, and exotic excitonic states. Such representative many-body correlations often dominate optoelectronic responses in systems with reduced dimensionality. For low-dimensional semiconducting TMDs, strong exciton confinement and reduced dielectric screening of associated Coulombic interactions can manifest upon radiative excitation (even—to an extent—bulk film conditions), resulting in strongly bound excitons which are stable at room temperature. Such physical conditions have allowed for unique pathways to modulate the optical properties (e.g., photoluminescence emission) of monolayer TMDs not observed in bulk film analogs. Overall, such photophysical conditions represent a resurgence in TMD material-property assessments with a promise toward next-generation photonic applications.

Herein, we demonstrate broadband tailoring of monolayer MoS₂ optical properties via reversible physisorbed n- and p-type chemical dopants. Influence from chemical dopants exemplifies the challenging many-body excitonic effects discussed where changes in charge carrier density and local dielectric fields are both expected. Chemical dopant effects may also induce lattice distortions resulting in band renormalization. In contrast to exclusive voltage gating (i.e., electrical doping) only showing shifts in excitons near the Fermi level, we describe our Δn responses with chemical adsorbates as manifesting due to dopant-induced charge transfer and dielectric field screening effects (i.e., screening of MoS₂ Coulombic potential). We define this cumulative influence as dopant-induced screening throughout, which represents shifts in excitons near the Fermi level and changes in high energy excitons thereby resulting in a broadband modulation of MoS₂ n . This is shown in relation to both exciton absorption and polarizability coinciding with controlled changes to n—where changes in n are more than an order of magnitude larger than is observed with contemporary semiconductor materials. These effects on exciton optical dispersion are characterized using variable angle spectroscopic ellipsometry with respect to metal organic chemical vapor deposited (MOCVD) monolayer MoS₂ films. Spectroscopic ellipsometry is ideal for our purposes as spectral excitonic features in the anomalous optical dispersion regime may be directly compared from as-prepared “pristine” monolayer film conditions to films after introducing the physicochemical alteration.

Specifically, spectroscopic ellipsometry measurements of monolayer MOCVD MoS₂ films are taken pre- and post-modification with n- and p-type chemical adsorbates (i.e., nicotinamide adenine dinucleotide, NADH, and 7,7,8,8-tetracyanoquinodimethane, TCNQ, respectively). We likewise assessed the reversibility of such dopant-induced screening effects by removing the physisorbed chemical species. Lastly, we also characterize MOCVD MoS₂ film quality to ensure variations from reported optical properties are not attributed to undesired film degradation.

Understanding the extent and origin of such representative changes in optical response is expected to expand the applicability of TMDs toward high-efficiency optical components, low-dimensional exciton optoelectronic devices, and electroabsorption modulators.

Preliminary studies assessing TMD optical constant modulation via excitonic effects have focused on layer-dependent quantum confinement (i.e., monolayer to bulk film transitions). However, complementary studies (e.g., showing control over charge carrier density) suggest the potential for alternative film conditions to influence monolayer TMD optical constants given observed changes in exciton absorption and polarizability. For example, the dielectric environment has been shown to have a profound impact on both electronic mobility and photoluminescence (PL) intensity. Similarly, controlled increases and decreases in monolayer MoS₂ exciton PL intensity in the presence of p- and n-type physisorbed chemical dopants, respectively, have been observed. Such physisorbed doping strategies have been described as convenient methods to modify the carrier density of 2D materials, having also been observed with graphene and carbon nanotubes. We expand on these representative observations for monolayer and layered TMDs by further illustrating the impact of dopant-induced screening effects on MOCVD monolayer MoS₂ optical constants from 300-3000 nm. Here, dopant-induced screening effects are investigated using exemplary n-type (NADH) and p-type (TCNQ) chemical adsorbates. Compared to a standard hydrogen electrode, the flat band potential of few layer exfoliated MoS₂ is around −0.13 eV, the oxidation potential of NADH is −0.32 eV, and the reduction potential for TCNQ is 0.46 eV. As such, assuming predominant electrical doping conditions suggested by others, NADH is expected to induce electron injection while TCNQ is expected to induce electron extraction with respect to our monolayer MOCVD MoS₂ films.

Variable angle spectroscopic ellipsometry is used throughout this work to derive MOCVD MoS₂ film optical constants. For each measurement, a Lorentz multi-oscillator model was analytically applied to derive the optical constants from the raw optical dispersion data. Experimental dispersion data directly corresponds to collective MoS₂ spectral exciton profiles in the UV/vis regime. The complex Lorentz formalism is defined as

$$\tilde{ɛ} ( ω ) = {ɛ}_{o} + {\sum }_{k = 1}^{n} \frac{{f}_{k}}{{ω}_{k}^{2} - {ω}^{2} - i {ωγ}_{k}} \qquad ( 1 )$$

where εₒ is the permittivity of free space, fₖ is the resonant oscillator amplitude strength, γₖ is the resonant peak oscillator width, and Ωₖ is the resonant peak oscillator wavelength for the k-th oscillator. Lorentz parameterization therefore permits an assessment with respect to exciton oscillator amplitude strength along with peak width and excitation wavelength. The complex dielectric function (\tilde{ε}=ε₁+iε₂) is often compared to the complex refractive index (ñ=n+ik) throughout this work to better illustrate exciton modulation and polarizability due to reported dopant-induced screening effects. Equation 1 is likewise used for these derived data, reported as a function of energy (E) instead of Ω, where ε₁=n²−k² and ε₂=2nk .

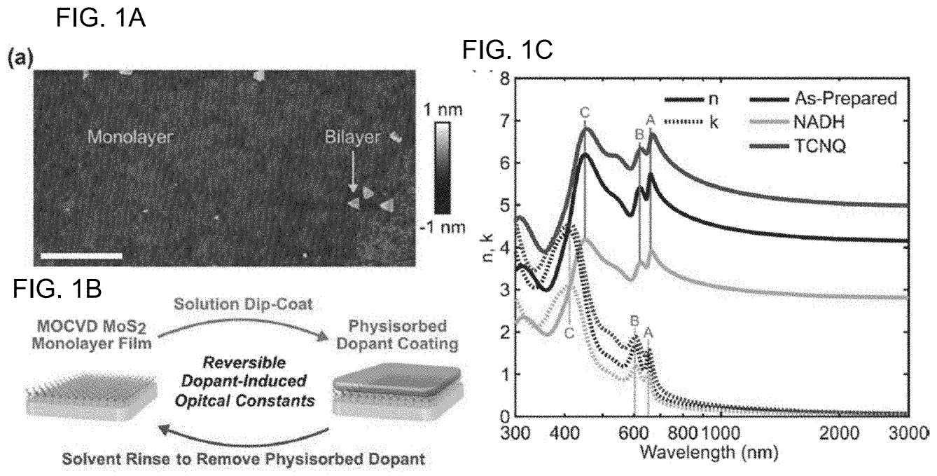

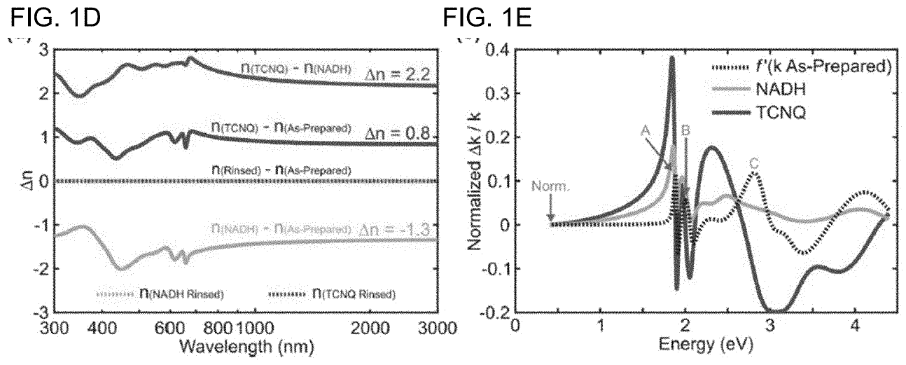

MOCVD MoS₂ films on C-plane single-side polished sapphire are used in the method disclosed herein. Overall, our approach yields predominantly monolayer thick films as shown in the atomic force microscopy (AFM) micrograph in FIG. 1A. Our dopant-induced screening assessment of optical responses is simple involving a solution dip-coat and subsequent solvent rinse shown in FIG. 1B. The MOCVD MoS₂ optical constants for the as-prepared film, with NADH, and with TCNQ adsorbates are shown in FIG. 1C (note n at 3000 nm for each film condition is as follows:
as-prepared n=4.2, with TCNQ n=5.1, and with NADH n=2.9). For baseline reference, the optical dispersion parameterization of this as-prepared film is provided in Table S1 (below) and has a preferentially low mean squared error (MSE) of 0.993. This film was then dip-coated in a 0.1 M solution of NADH in anhydrous acetonitrile, dried under N₂, and the optical constants derived from spectroscopic ellipsometry measurements. Under these conditions, the broadband optical constants significantly decrease compared to the as-prepared film response. Likewise, the rinsed film (rinsed responses are discussed below) was dip-coated in a 0.1 M solution of TCNQ in anhydrous methanol, dried under N₂, and the optical constants derived from spectroscopic ellipsometry. Here, n values significantly increase compared to the as-prepared film response. ‘Rinsing’ refers to the reversibility of the process, meaning that the physical dopant interactions do not appear to be permanent. Rinsing indicates a method to simply wash away the adsorbates with a selected solvent. The processes are reversible in the sense that the adsorbates are not permanently attached. However, this is not always the case (e.g., for liquid phase exfoliated TMDs with POMs or lithium-oxide complexes). The rinsed film is the film being rinsed, and that was previously dip-coated with NADH or TCNQ.

TABLE S1
Lorentz multi-oscillator parameters for the as-prepared,
NADH, and TCNQ MOCVD MoS₂ responses shown in FIG. 1.

| | Oscil- | Oscil- | Oscil- | Oscil- | Oscil- | Oscil- |
|---|---|---|---|---|---|---|
| Lorentz | lator | lator | lator | lator | lator | lator |
| Parameter^{a} | 1 | 2 | 3 | 4 | 5 | 6 |

As-Prepared MOCVD MoS₂ Film (MSE = 0.993)

| | | | | | | |
|---|---|---|---|---|---|---|
| Amp^{b} | 8.461 | 10.597 | 4.693 | 34.777 | 11.359 | 25.066 |
| Br^{c} | 0.057 | 0.155 | 0.441 | 0.469 | 0.536 | 1.246 |
| En^{d} | 1.895 | 2.038 | 2.346 | 2.887 | 3.173 | 4.255 |

NADH MOCVD MoS₂ Film (MSE = 0.879)

| | | | | | | |
|---|---|---|---|---|---|---|
| Amp | 4.031 | 4.886 | 2.\|639 | 17.072 | 4.546 | 11.254 |
| Br | 0.071 | 0.169 | 0.527 | 0.470 | 0.527 | 1.144 |
| En | 1.880 | 2.028 | 2.369 | 2.884 | 3.171 | 4.187 |

TCNQ MOCVD MoS₂ Film (MSE = 1.437)

| | | | | | | |
|---|---|---|---|---|---|---|
| Amp | 9.198 | 11.906 | 9.633 | 38.023 | 15.960 | 41.395 |
| Br | 0.091 | 0.198 | 0.457 | 0.537 | 0.700 | 1.077 |
| En | 1.881 | 2.031 | 2.343 | 2.872 | 3.227 | 4.297 |

^{a}The variables shown here are those used in the computational software. They are related to Equation 1 in the main text as follows;
^{b}Amp is unitless amplitude where f = Amp · Br · En in units of eV².
^{c}Br is the broadness of the peak where γ = Br in units of eV.
^{d}En is the energy of the peak in units of eV.
Note that Equation 1 is as a function of wavelength (ω) as this is depicted throughout each dispersion plot in lieu of photon energy.

FIGS. 1A-1E illustrate the impact of physisorbed dopant-induced screening effects on the optical constants of MOCVD MoS₂. A single MOCVD MoS₂ film is used to demonstrate the tailoring of optical constants observed in FIGS. 1A-1E. This serves to illustrate the reversibility of observed responses under presumed physisorbed electrostatic interfacial interactions (compare FIG. 1B). After each assessment with a given adsorbate, the MOCVD MoS₂ film is gently rinsed with the respective solvent (i.e., anhydrous acetonitrile for NADH and anhydrous methanol for TCNQ) and dried under N₂. After rinsing and drying, the optical constants are assessed again and compared to the as-prepared film response. The difference in optical response is determined from the derived data and found to be Δn≈0 after each rinse (FIG. 1D). This is indicative of equivalent dispersion model parameterization for the as-prepared and rinsed films with mean squared errors (MSEs)<1. Note a simple Cauchy model is included (in addition with the Lorentz multi-oscillator model) in evaluation of the dip-coated physisorbed film conditions, and in each case a similar film thickness of 20-30 nm was derived for the adsorbate coatings. The Cauchy model was unnecessary after each solvent rinse and subsequently omitted, yielding as-prepared film conditions. Although reported data represents only one film, characteristic dopant-induced changes in optical constants were confirmed with multiple MOCVD MoS₂ films showing little variation in magnitude relative to the film handling conditions outlined in this work.

To quantify the change in n, Δn with respect to the as-prepared film as well as between the adsorbate film conditions are shown in FIG. 1D. At 3000 nm (well below the exciton band edge), these representative responses correspond to Δn=−1.3 for NADH compared to the as-prepared film, Δn=0.8 for TCNQ compared to the as-prepared film, and total Δn=2.2 between NADH and TCNQ film conditions. Intriguingly, exciton absorption from adsorbate film conditions observed in FIGS. 1C-1D appear to impact each spectral exciton response (as opposed to the limited spectral range afforded by PL to-date. Indeed, changes in f (i.e., peak k oscillator amplitude strength or exciton absorption) for every oscillator represent the most dramatic changes in optical dispersion parameterization with respect to such notable Δn (model parameters are provided in Table S1 above).

Compared to prior work, which assumes predominant charge transfer electron injection or extraction with physisorbed chemical dopants, our responses extend to each measured exciton. This additional exciton modulation at higher energies is unexpected assuming purely charge transfer doping effects. For instance, it is known that A and B exciton intensities (i.e., those closest to the Fermi level) are largely impacted by changes due to an applied voltage bias offering comparably minimal change in n at energies below the band edge. We discovered similar changes to the A and B exciton amplitudes with respect to charge transfer effects; however, modulation in the C exciton is also observed, suggesting additional influence to voltage gating. This is observed in FIG. 1E where the normalized change in k (Δk) divided by k at ˜0.4 eV (3000 nm) of each film is shown in relation to the first derivative of k of the as-prepared film. Below 2.2 eV the similarity between the Δk/k plots and the first derivative of k indicates chemical doping results in a slight redshift, broadening, and reduction of the A and B exciton absorption peaks. Consistent with our discussion regarding charge transfer doping of the A and B excitons, behavior for normalized Δk/k NADH and TCNQ responses show very similar peak profiles to the as-prepared film.

However, subsequent oscillator activity at energies greater than ˜2.2 eV (i.e., beyond the A and B excitons) is very different—suggesting changes not exclusive to charge transfer doping effects.

A potential source of further exciton modulation is expected given the polarizability of low-dimensional systems to dielectric field screening effects. For example, PL intensity of monolayer MoS₂ excitons are known to be strongly correlated to the surrounding dielectric environment (e.g., organic and nonionic solvents). Reported changes in PL emission intensity with respect to solvent environment are similar to those observed with n- and p-type adsorbates in the literature showing, for example, A-trion and A exciton recombination. Some attribute PL modulation to a dielectric field screening effect of the Coulomb potential while others attribute it to exciton recombination effects due to electron injection or extraction from n- and p-type chemical dopants. Given these observations regarding A, B exciton charge transfer electron doping and dielectric field screening, in conjunction with the higher energy exciton modulation shown in our work, we conclude that both charge transfer doping and dielectric field screening occurs in relation to n- and p-type chemical adsorbates. As a result, this would suggest (based on similar work discussed) the modulation we observe in n occurs due to both charge transfer induced exciton recombination and screening of the Coulomb potential to some extent for all measurable excitons. Within the context of our responses, this suggests cumulative dopant-induced screening influences monolayer MOCVD MoS₂ optical constants where dielectric field screening is perhaps more influential to the observed Δn magnitude in FIGS. 1C-1D.

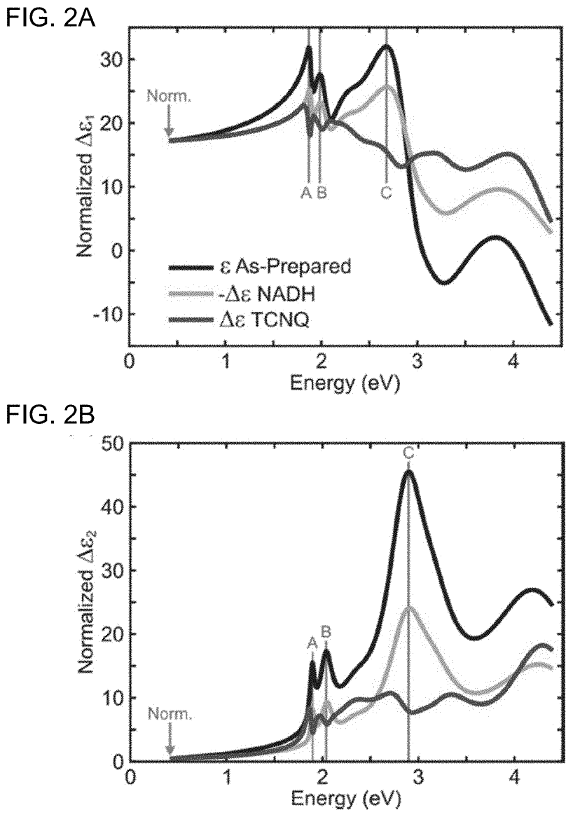

In comparison to changes in k shown in FIG. 1E, the impact of dopant-induced screening on polarizability is shown in FIG. 2A where normalized Δε at ˜0.4 eV (3000 nm) is compared to the as-prepared ε1 response. Here, the −Δε1 spectral profile for NADH is not so different from the as-prepared film exciton characteristics. This is likewise the case for ε2 as shown in FIG. 2B for −ε2 NADH. Note, ε2 is a measure of dissipative dielectric losses due to electronic resonances at optical frequencies. Therefore, reductions in ε2 in this region is a clear indicator of decreasing absorption cross sections for the A, B, and C excitons. Similar exciton profile characteristics are expected with NADH as HOMO and LUMO energy levels near the Fermi level are observed, perhaps providing a deep level local state, which may dampen band-to-band recombination without establishing new energy states near MoS₂ band edge levels.

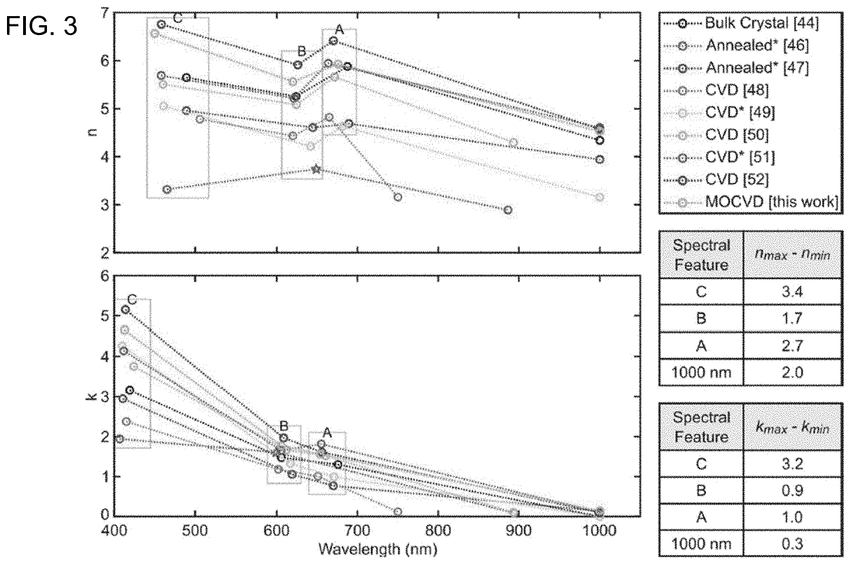

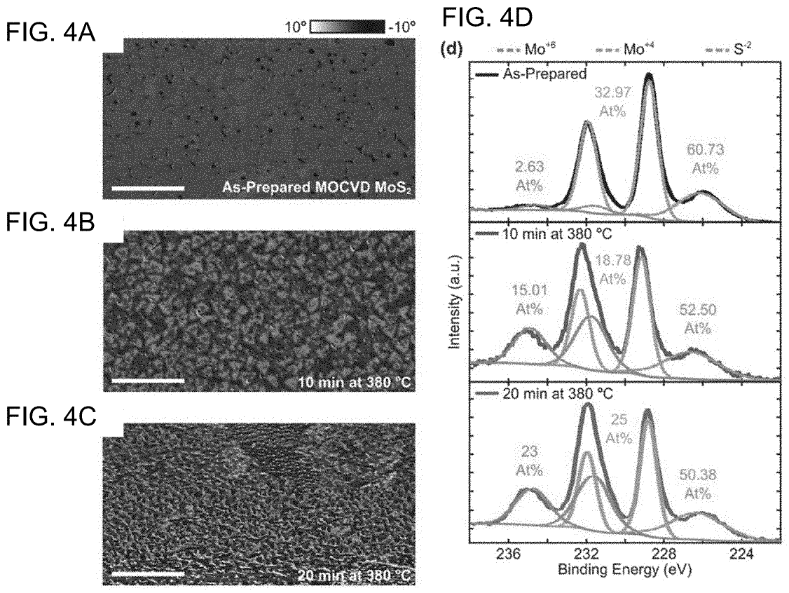

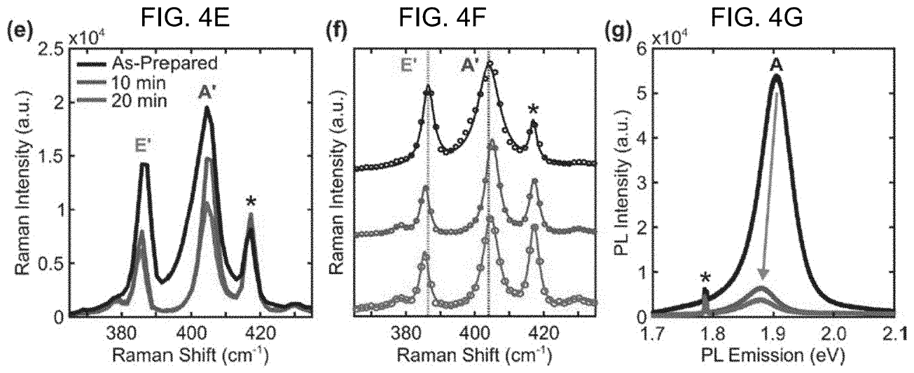

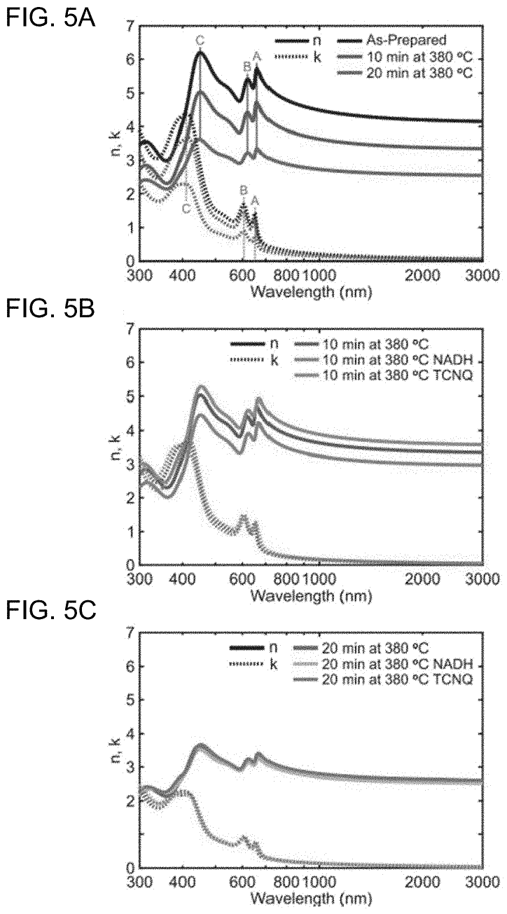

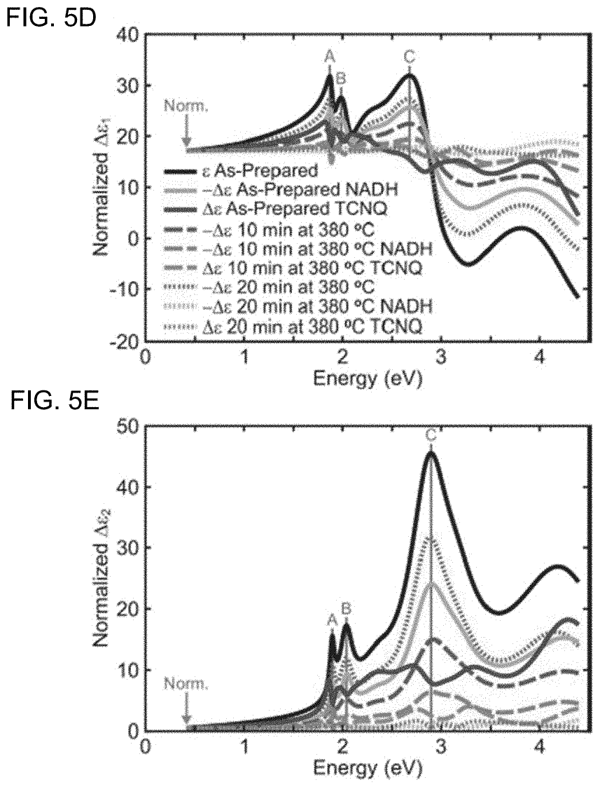

FIG. 3 presents a comparison of MoS₂ n and k literature values related to A, B, and C peak exciton responses as well as out to 1000 nm where possible. If not reported, the values closest to 1000 nm below the band edge are plotted. Here, responses correspond to a single bulk crystal, 1.99 nm annealed film, 12 nm annealed film, 0.7 nm CVD film, 0.63 nm CVD film, 0.7 nm CVD film, 0.7 nm CVD film, 0.7 nm CVD film, and a representative 0.7 nm MOCVD film used in this work. The asterisk in the legend indicates plotted values were analytically reproduced from reported model parameters. The star symbol in the dispersion plots indicate there is no clear distinction between the A and B excitons in their reported data.

However, the Δε responses in FIGS. 2A-2B for TCNQ are noticeably different. The potential for new energy states is expected as LUMO energy levels for TCNQ appear on top of the band edge levels for monolayer MoS₂. It is also worth noting we observe a redshift for both n- and p-type adsorbates whereas a redshift is observed for an n-type dopant and a blueshift for p-type dopants in complementary PL studies. There are several possibilities as to why this is observed including, for example, differences in film synthesis (i.e., exfoliation, vs. CVD, vs. MOCVD) as well as MoS₂ edge site vs. basal plane adsorbate exposure. Furthermore, suggested influence from combined dopant-induced screening effects between chemical adsorbates and monolayer materials is expected to be highly sensitive to overall monolayer film quality as well as dopant saturation effects (e.g., morphological strain resulting in exciton absorption interference).

For instance, charge transfer complexes exhibit the potential to modify the density of states in organic semiconductors. While there are no distinct resonances in our responses to suggest this is occurring with MoS₂, this remains a possibility for inorganic low-dimensional materials. Given these various dopant-induced considerations, correlated exciton activity may fluctuate with respect to a given adsorbate interaction and thereby impact the overall efficiency of the dopant-induced response. As a qualitative example, the p-type TCNQ films yield fits with MSEs between 1 and 2 while the NADH films yield fits with MSEs<1 (similar to the as-prepared film dispersion parameterization). While still very low MSEs, it is possible for strong electron extraction effects to cause slightly larger MSEs in relation to the as-prepared film. Indeed, this may be a possible cause for lower |Δn1| values for TCNQ compared to NADH (FIG. 1D). Overall, such physicochemical conditions represent the previously mentioned many-body excitonic effects and complementary phenomenological characterization which will be the focus of future work. Perhaps most significant in the many-body exciton consideration, we show that the magnitude of such dopant-induced screening effects is highly sensitive to overall film quality, discussed below. As may be expected, it is likely that film or material quality will ultimately dictate the applicability of physisorbed dopant-induced screening to tailor TMD optical constants.

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

Semiconductor transition metal dichalcogenide (TMD) films are brought into proximity of a chemical dopant. In this work, chemical vapor deposited TMDs films were dip-coated in a representative dopant solution. Exemplary chemical dopants used include n-type nicotinamide adenine dinucleotide (NADH) and p-type 7,7,8,8-tetracyanoquinodimethane (TCNQ). In relation to TMDs, an n-type dopant is expected to induce electron injection while a p-type dopant is expected to induce electron extraction with respect to the representative semiconducting TMD film. While charge transfer effects are expected as described, we observe that this response is also attributed to dielectric field screening effects. As a result, we describe this combined effect as dopant-induced screening.

The illustration of changing the optical constants of TMDs was likewise shown using exfoliation species known as polyoxometalates, POMs, (i.e., metal oxide complexes) used in the redox exfoliation of bulk crystal TMDs. These are highly charged inorganic complexes that predominantly behave as n-type dopants.

Dopant-induced screening of TMD films evaluated to-date include those prepared from chemical vapor deposition, physical vapor deposited two-step annealing, and liquid phase exfoliation methods. TMDs include 2D flakes and films as well as 3D platelets and films. Representative semiconducting TMDs include MoS₂, MoSe₂, MoTe₂, WS₂, WSe₂, and WTe₂.

To-date, dopant-induced optical constant tailoring has been experimentally observed with MoS₂, MoSe₂, WS₂, WSe₂, and TiS₂ from chemical and physical vapor deposition methods. These films involved NADH, TCNQ, and POMs, Dopant-induced optical constant tailoring has also been experimentally observed with MoS₂, MoSe₂, WS₂, WSe₂, and TiS₂ from liquid phase exfoliation. This has been with the inherent POMs used in exfoliation and with NADH or TCNQ.

Dopant species can be organic or inorganic in chemical structure. Note that doping here is considered extrinsic to the TMD lattice. This means TMD doping is not in the form of TMD lattice atomic substitution.

### 1. Monolayer MOCVD MoS₂ Film Synthesis

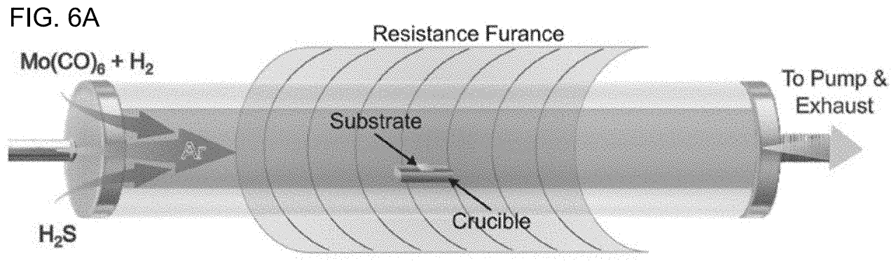

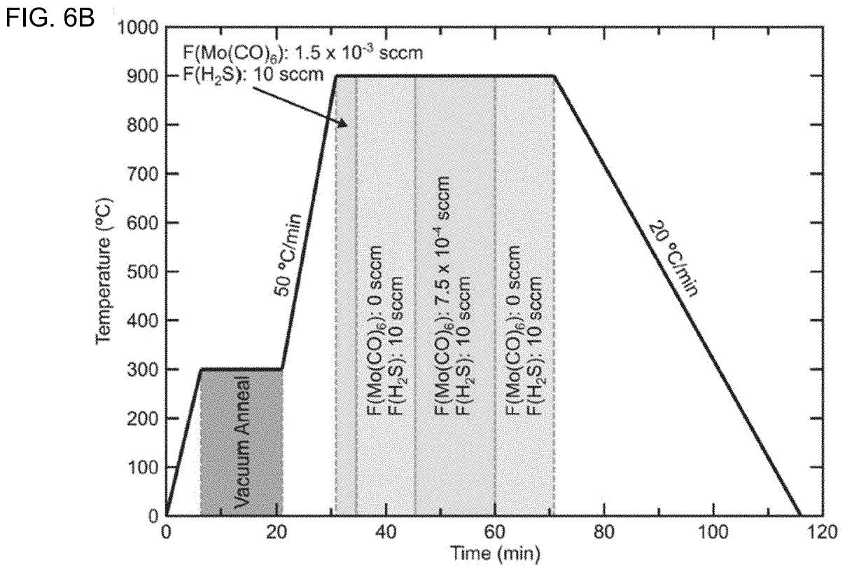

MoS₂ films were grown by metal organic chemical vapor deposition (MOCVD) in a home-built horizontal hot-wall system (FIG. 6A). High purity Mo(CO)₆ (99.9%, Sigma-Aldrich) is placed in a stainless-steel bubbler in an argon-filled glove box and functions as the molybdenum source. Throughout the growth process (FIG. 6B) the temperature of the Mo(CO)₆ bubbler is kept at 20-30° C., e.g. 24° C. and the pressure is regulated at 700-800 Torr, e.g. 735 Torr. The sulfur is supplied by a 500 ml H₂S (99.5%, Sigma-Aldrich) lecture bottle with an outlet pressure of 25-35 psi, e.g. 30 psi.

Prior to growth, the main chamber is pumped down to base pressure (20 mTorr) and allowed to reach a temperature of 300° C. for 15 minutes to remove moisture and other organic contaminants. Following this step, the system is pressurized with argon to the growth pressure (50 Torr) and ramped up to the growth temperature (900° C.) at a rate of 50° C./min. 2 slm of argon gas is flown through the main chamber during the entire growth process to achieve laminar flow and push gaseous precursors downstream to the growth substrate. When the system reaches 900° C., 7.5 sccm H₂ gas is flown through the Mo(CO)₆ bubbler and into the chamber for 2 minutes while maintaining a H₂S flow of 10 sccm to form metal-rich nuclei on the substrate surface. Knowing Mo(CO)₆ bubbler temperature and pressure and based on Mo(CO)₆ vapor pressure, this corresponds to a Mo(CO)₆ flow of 1.5×10⁻³ sccm which highlights the fact that the growth occurs in a chalcogen-rich environment. After this nucleation step, a 10 minute ripening step (where the Mo(CO)₆ flow is stopped) allows the nuclei to laterally grow.

Following the ripening step, film coalescence is achieved by resuming Mo(CO)₆ flow at a reduced flow rate of 3.75 sccm for 15 minutes. After reaching complete monolayer coalescence, a 10 minute post growth anneal at 900° C. with a 10 sccm H₂S flow is used to reduce the number of metal-rich particles on the surface and the density of sulfur vacancies resulting from the growth process. The system is then fan cooled from the growth temperature down to room temperature at a rate of 20° C./min.

### 2. Representative Optical Dispersion Parameterization

The fitted parameters for a representative as-prepared monolayer MOCVD MoS₂ film is provided for comparison in Table S1. The parameterization of this film is carried out using a Lorentz multi-oscillator optical dispersion model (see Equation 1). Here, six oscillators are used.

This is consistent with many of the multi-oscillator models employed for the responses compared in FIG. 2. Reported parameters are based on notation and units used in the CompleteEASE (J. A. Woollam) computational software and defined in relation to Equation 1 in the Table S1 footnotes.

### 3. MoS₂ Optical Constants Comparison

For future comparison of the responses in FIG. 2, the plotted optical constant values are tabulated in Table S2 for convenience. These data are presented with respect to the magnitude of n and k in relation to the given peak excitation wavelength. In most cases, the reported experimental data extend to (or beyond) 1000 nm; however, some do not and those responses are indicated. Additionally, some studies report model parameterization (as we do in Table S1 for an as-prepared monolayer MOCVD MoS₂ film) and were used to analytically reproduce derived responses. Those studies are likewise indicated in Table S2.

TABLE S2
MoS₂ optical constant literature values compared in FIG. 2.

| | | | | |
|---|---|---|---|---|
| Main Text | | | | |
| Literature | C | B | A | |
| Reference | Exciton | Exciton | Exciton | 1000 nm |

Refractive index (n)

| | | | | | |
|---|---|---|---|---|---|
| [44] | 5.647 | 5.254 | | 5.878 | 4.340 |
| [46]^{a} | 3.318 | | 3.741^{b} | | 2.889^{c} |
| [47]^{a} | 4.959 | 4.605 | | 4.687 | 3.941 |
| [48] | 4.780 | 4.432 | | 4.821 | 3.159^{c} |
| [49]^{a} | 5.054 | 4.216 | | 4.635 | 3.156 |
| [50] | 5.506 | 5.084 | | 5.660 | 4.295^{c} |
| [51]^{a} | 5.690 | 5.216 | | 5.943 | 4.607 |
| [52] | 6.756 | 5.911 | | 6.414 | 4.577 |
| [this work] | 6.564 | 5.562 | | 5.926 | 4.529 |

Refractive index (n) wavelength (nm)

| | | | | | |
|---|---|---|---|---|---|
| [44] | 489 | 624 | | 688 | 1000 |
| [46]^{a} | 465 | | 649^{b} | | 887^{c} |
| [47]^{a} | 489 | 645 | | 689 | 1000 |
| [48] | 506 | 620 | | 665 | 750^{c} |
| [49]^{a} | 461 | 642 | | 682 | 1000 |
| [50] | 460 | 624 | | 672 | 893^{c} |
| [51]^{a} | 458 | 621 | | 664 | 1000 |
| [52] | 458 | 626 | | 670 | 1000 |
| [this work] | 450 | 620 | | 676 | 1000 |

Extinction coefficient (k)

| | | | | | |
|---|---|---|---|---|---|
| [44] | 3.156 | 1.472 | | 1.300 | 7.450 × 10⁻⁴ |
| [46]^{a} | 1.939 | | 1.607^{b} | | 0.091^{c} |
| [47]^{a} | 2.946 | 1.054 | | 0.769 | 0.138 |
| [48] | 2.374 | 1.180 | | 1.006 | 0.120^{c} |
| [49]^{a} | 4.263 | 1.326 | | 0.991 | 0 |
| [50] | 3.752 | 1.667 | | 1.517 | 0.105^{c} |
| [51]^{a} | 4.139 | 1.657 | | 1.812 | 0.104 |
| [52] | 5.151 | 1.965 | | 1.608 | 0.105 |
| [this work] | 4.651 | 1.766 | | 1.560 | 0.143 |

Extinction coefficient (k) wavelength (nm)

| | | | | | |
|---|---|---|---|---|---|
| [44] | 419 | 606 | | 676 | 1000 |
| [46]^{a} | 407 | | 599^{b} | | 894^{c} |
| [47]^{a} | 411 | 619 | | 670 | 1000 |
| [48] | 415 | 602 | | 615 | 750^{c} |
| [49]^{a} | 410 | 617 | | 671 | 1000 |
| [50] | 424 | 612 | | 661 | 893^{c} |
| [51] | 412 | 606 | | 655 | 1000 |
| [52] | 414 | 609 | | 656 | 1000 |
| [this work] | 413 | 606 | | 654 | 1000 |

^{a}These data were analytically reproduced based on reported parameters.
^{b}There is no obvious difference between the A and B excitons from Duesberg and coworkers and the response is merged between the A and B responses from other works.
^{c}These values reported at the 1000 nm location did not extend to this wavelength in the reported experimental studies. Such responses then correlate to the wavelength values indicated.

### 4. Consideration of Alternative Optical Dispersion Models

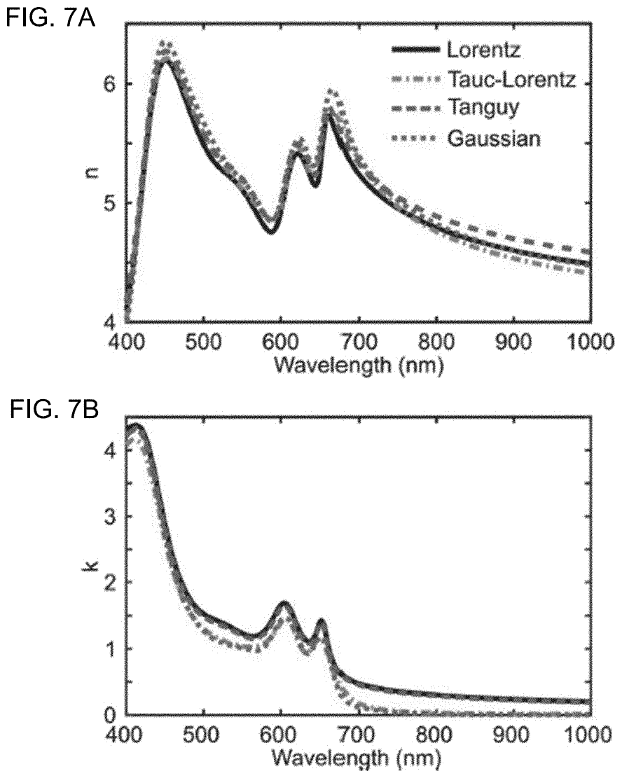

The Lorentz oscillator model has often been employed to derive the optical constants of MoS₂ films. However, alternative dispersion models may be implemented as has been done for other semiconductor systems. Here, we compare alternative dispersion models to the typical Lorentz formalism and derived dispersion responses of a representative as-prepared MOCVD MoS₂ film are compared in FIGS. 7A-7B.

Lorentz parameterization represents values provided in Table S1. Overall, there is little variation in the responses shown in FIGS. 7A-7B; however, there are some important observations to point out with respect to both model parameterization and derived optical constant dispersion.

A common alternative for analogous semiconducting systems is the Tauc-Lorentz model.

This approach combines a Tauc empirical expression for the band edge onset along with the peak broadening given by the classical Lorentz oscillator. This model is often applied for amorphous or crystalline semiconductors and includes the band gap in addition to the typical Lorentz parameters. A concern with the Tauc-Lorentz model is the subsequent use of four parameters per oscillator. This is potentially problematic given three to seven oscillators are commonly used for as-prepared MoS₂. Still, Tauc-Lorentz parameterization was used for tabulated Kramers-Kronig derived data. Intriguingly, this tabulated parameterization results in the profile characteristics in k that approximate the observed response (i.e., the sharp drop in magnitude beyond the exciton band edge; e.g., 7.5×10⁻⁴ at 1000 nm). We use a Tauc-Lorentz model and the derived optical constants are shown in FIGS. 7A-7B illustrating similarly low k values beyond the band edge. A MSE of 0.909 was obtained for this fit.

The Tanguy dispersion model is another alternative which takes into account electronic transitions with respect to the band gap and assumed Wannier excitonic effects. As such, it is possible to derive values for physical parameters including the optical band gap and exciton binding energy along with typical Lorentz parameterization. As with the Lorentz oscillator, the absorption tail beyond the band edge is higher which may not be the most accurate physical representation. Overall, this model includes five parameters per oscillator. As such, the derived responses may potentially be underdetermined depending on overall film quality; however, this is unlikely in the assessment of our as-prepared film in FIGS. 7A-7B where an MSE of 0.983 is obtained. Still, given the potential to qualitatively evaluate expected phenomenological excitonic effects, the Tanguy model remains an appealing approach for future work discussed in the main text.

Lastly, the Gaussian dispersion model is a likely alternative and our derived response is shown FIGS. 7A-7B representing a MSE of 0.733. Here, three parameters per oscillator are used (similar to the Lorentz formalism); however, the Gaussian model does not have such broadened peak tails. As a result, this model is an appealing alternative as it is likely more representative of the absorption tail beyond the exciton band edge shown in FIG. 7B. While similar to the Tauc-Lorentz drop in k, the Gaussian model has fewer parameters per oscillator. As such, the Gaussian model can likely be used in future studies to yield simpler, robust fits for MoS₂ optical constants that are perhaps physically more representative in relation to the Lorentz model. Of course, this would likely assume there are negligible influences beyond dopant-induced screening effects.

### 5. Quantum Confined Excitonic Effects

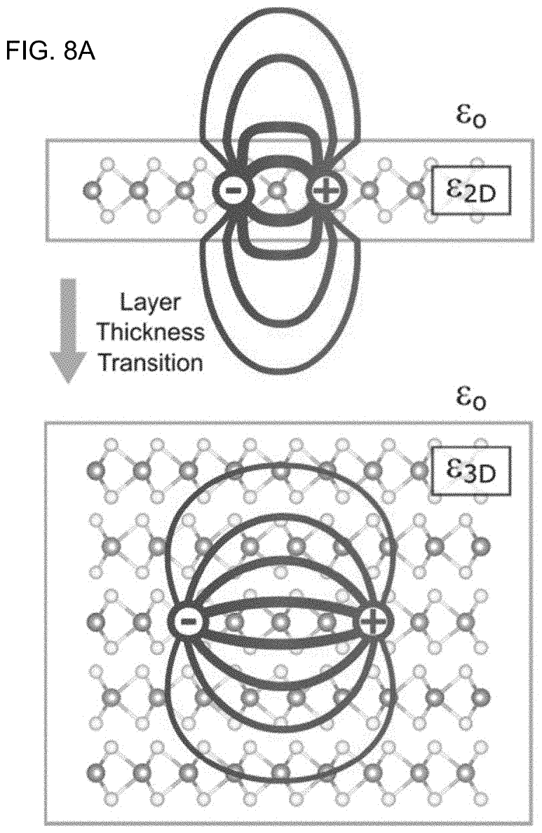

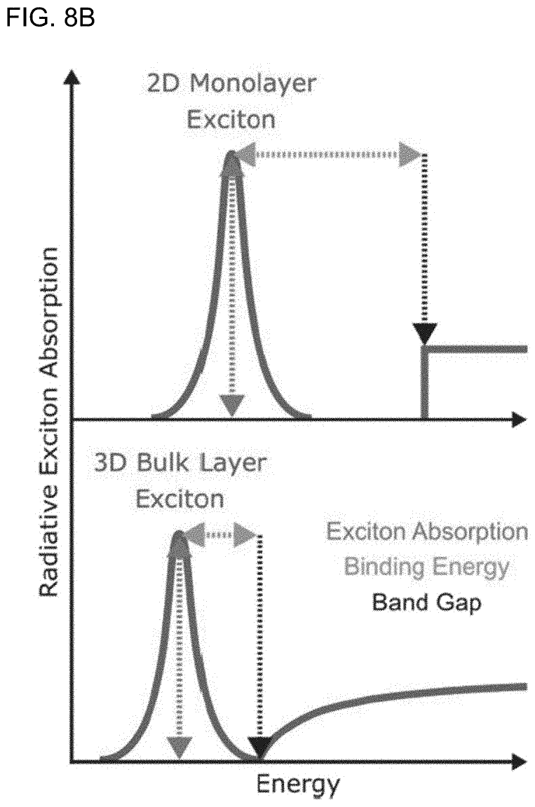

Mentioned in the main text are the influences of quantum confinement resulting in layer-dependent electric-field screening effects on the optical responses of TMDs. For visualization, layer-dependent effects are schematically shown in real-space in FIG. 8A and the qualitative impact on exciton absorption in FIG. 8B. FIG. 8A presents a representative real-space depiction of electrons and holes bound into excitons for 2D monolayer MoS₂ and 3D bulk layer MoS₂. In the case of layer-dependent MoS₂ quantum confinement, transition into bulk layer effects is observed to occur around ˜5 layers. Changes in the dielectric environment, due to representative exciton activity, are indicated schematically by ε2D and ε3D in relation to the permittivity of free space εo.

FIG. 8B presents the qualitative impact of dimensionality on exciton absorption are schematically represented by optical absorption for monolayer excitons and bulk layer excitons. The transition from 2D to 3D is known to lead to a decrease of both the band gap and the exciton binding energy (black vertical arrow and horizontal teal double-sided arrow, respectively). This likewise corresponds to a decrease in exciton absorption with respect to a perfectly monolayer film (vertical orange double-sided arrow).

### 6. Additional Raman and Photoluminescence Spectroscopy Film Characterization

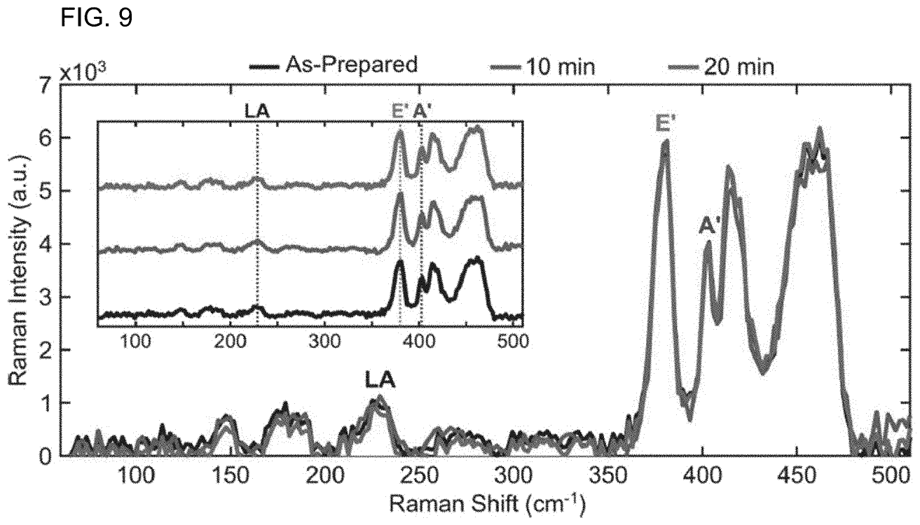

Lattice defects (e.g., in the form of chalcogen vacancies and oxidation) are known to impact optoelectronic properties of monolayer TMDs. It has been observed that resonance Raman spectroscopy can approximate the extent of lattice defect density in relation to peak shifts and intensity changes in zone-center and non-zone center Raman peaks. The E′ and A′ modes correspond to in-plane Mo and S vibrations and out-of-plane S vibrations. The most prominent non-zone center mode is an asymmetric peak located ε225 cm⁻¹ resulting from a double resonance process from two longitudinal acoustic (LA) phonons with opposite momenta at the Brillouin zone boundary. As with typical defect-related Raman features, the LA peak is expected to increase in intensity with appreciable increase in lattice defects. This is a useful measure of defect density as any change in LA phonon intensity can be compared in relation to the E′ Raman peak. FIG. 9 presents resonant Raman spectra illustrating the longitudinal acoustic (LA) phonon in relation to E′ and A′. The minimal change in the LA phonon suggests there is very mild degradation of the films with ambient air annealing. In FIG. 9, we observe minor changes in intensity with respect to the zone-center modes and little to no change in the non-zone center mode. This suggests MOCVD MoS₂ lattice defect density upon ambient air annealing described in the main text results in mild film degradation, but it still results in significant changes to the optical properties.

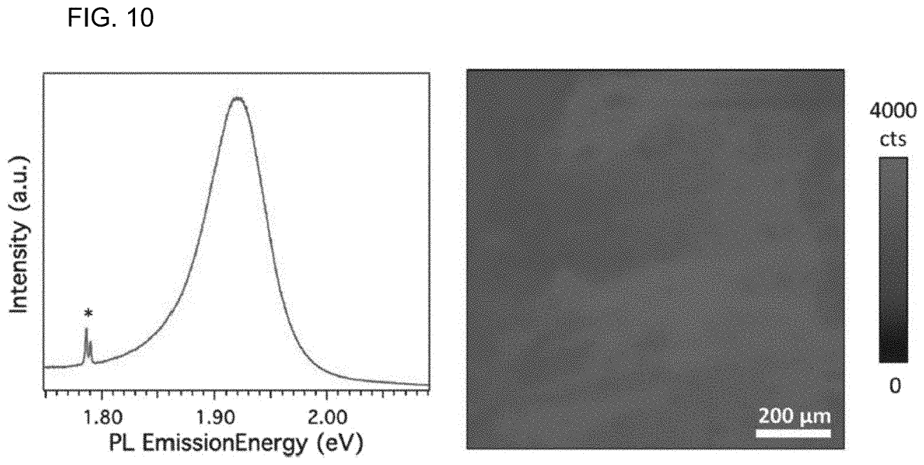

To further illustrate film monolayer uniformity, photoluminescence mapping is conducted of a 1 mm² area of an as-prepared MOCVD MoS₂ film, with spectra collected every 20 μm. FIG. 10 presents representative photoluminescence spectrum (left) and 2D intensity map from a 1 mm² area (right) of an as-prepared MOCVD MoS₂ film illustrating uniformity of A exciton emission intensity. Photoluminescence mapping area is on the order of the spot size used in spectroscopic ellipsometry. The (*) in the spectrum denotes the substrate. The 2D intensity map (FIG. 10) shows uniform A exciton emission. There is some deviation in response in FIG. 10 consistent with minor changes in layer thickness discussed in the main text; however, the photoluminescence mapping suggests largely uniform monolayer coverage.

While the observation of these effects is limited to simple dip-coating of representative films, TMD doping includes any strategy to chemically functionalize, encapsulate, passivate, or stabilize TMD flakes, platelets, or films. Encapsulation can include any strategy to encapsulate particles in a suspension or in a composite film, paint, or coating.

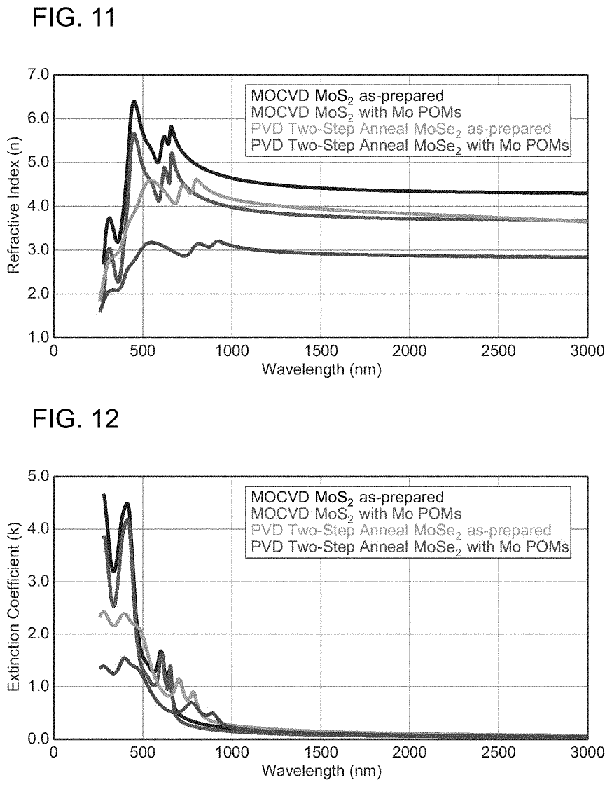

FIGS. 11-12 present data for MOCVD MoS₂ as discussed above. The changes in refractive index (n) and extinction coefficient (k) with Mo polyoxometalate dopant species are presented in FIGS. 11-12, respectively. FIGS. 11-12 also present refractive index (n) and extinction coefficient (k) data for MoSe₂ prepared from a physical vapor deposition (PVD) two-step anneal method.

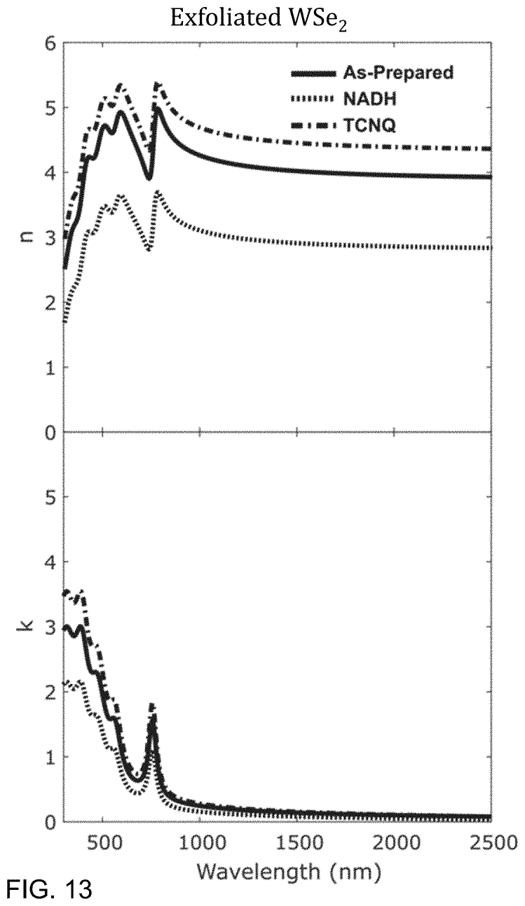

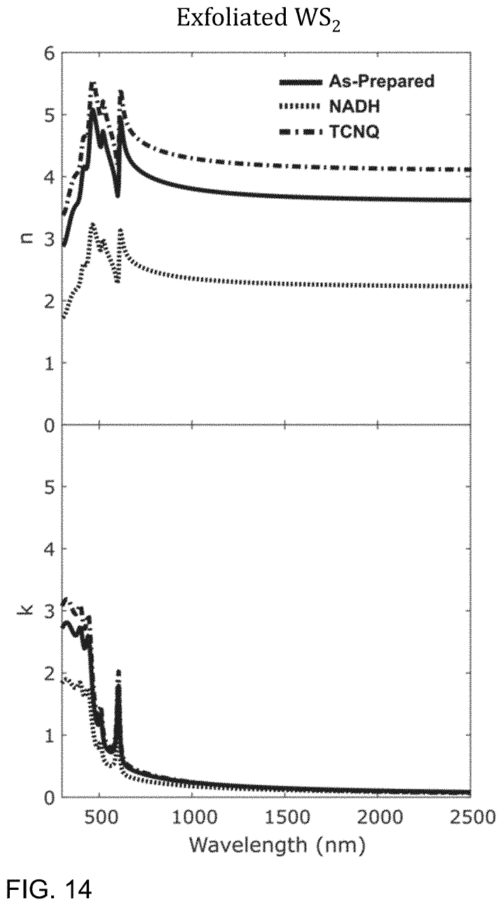

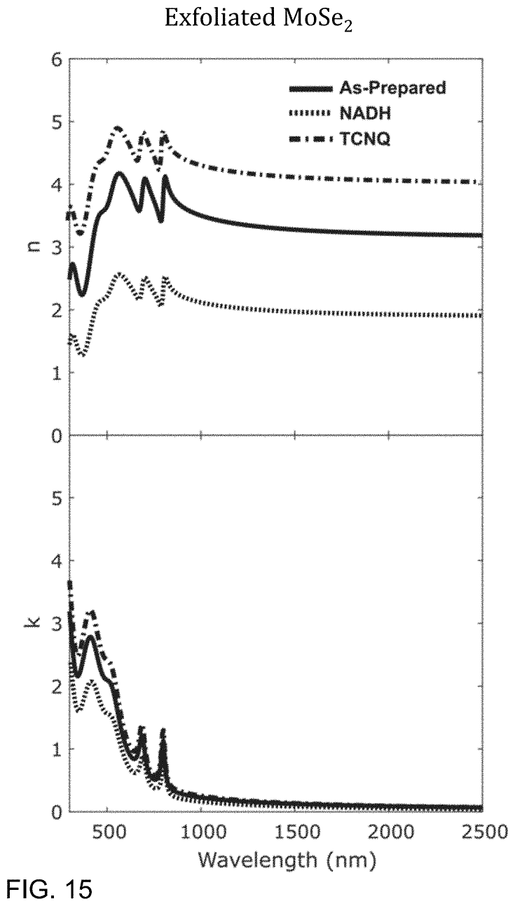

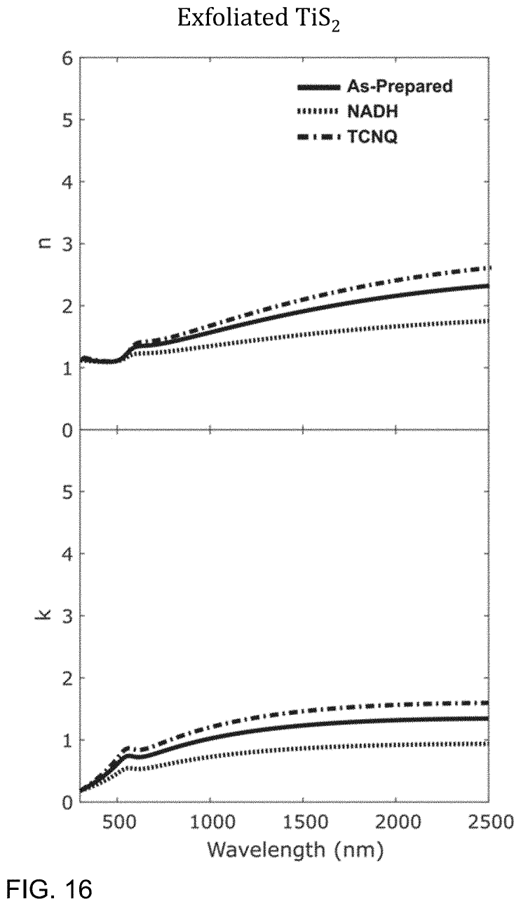

FIGS. 13-16 presents data for MOCVD WSe₂, WS₂, MoSe₂, and TiS₂, each of which was prepared by the same method described herein. The changes in refractive index (n) and extinction coefficient (k) with the respective dopant species, NADH and TCNQ, are presented in FIGS. 13-16, respectively

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A method for controlling the optical properties of a material, comprising the steps of:
applying a dopant to an undoped TMD film by solution dip-coating the TMD, wherein the solution is a dopant solution consisting of one of NADH (nicotinamide adenine dinucleotide) and TCNQ (7,7,8,8-tetracyanoquinodimethane), wherein the doped TMD film exhibits an altered refractive index (n) and extinction coefficient (k) in comparison to the undoped TMD film, wherein the TMD is at least one of MoS₂, MoSe₂, WS₂, WSe₂, and TiS₂.

2. The method of claim 1, wherein the dopant solution is a 0.1M solution of NADH in anhydrous acetonitrile.

3. The method of claim 1, wherein the dopant solution is a 0.1M solution of TCNQ in anhydrous methanol.

4. The method of claim 1, further comprising
rinsing the doped TMD film with a solvent consisting of one of anhydrous acetonitrile and anhydrous methanol to create an undoped TMD film exhibiting a refractive index (n) and extinction coefficient (k) substantially similar to the original undoped TMD film.

5. The method of claim 1, wherein the TMD is selected from the group consisting of MoS₂, MoSe₂, WS₂, WSe₂, and TiS₂.

6. The method of claim 1, wherein the TMD film is deposited onto the substrate by one of chemical vapor deposition (CVD), physical vapor deposition (PVD) with two-step annealing, and a liquid-phase exfoliation with or without polyoxometalates (POMs).
